(19) United States
(12) Patent Application Publication
(10) Pub. No.: US 2021/0364919 A1
(43) Pub. Date: Nov. 25, 2021

(54) PHOTOSENSITIVE RESIN COMPOSITION AND APPLICATION THEREOF

(71) Applicant: MICROCOSM TECHNOLOGY CO., LTD., Tainan City (TW)

(72) Inventors: Tang Chieh Huang, Tainan City (TW); Chau Chin Chuang, Tainan City (TW); Yu Chiao Shih, Tainan City (TW)

(73) Assignee: MICROCOSM TECHNOLOGY CO., LTD., Tainan City (TW)

(21) Appl. No.: 16/970,546

(22) PCT Filed: Jan. 23, 2019
(86) PCT No.: PCT/CN2019/072808

§ 371 Date: Aug. 17, 2020

(51) Int. Cl. G03F 7/037; C08G 69/44

(52) U.S. Cl. CPC G03F 7/037; C08G 69/44

(57) ABSTRACT

The present invention provides a photosensitive resin composition comprising (a) a polyamide ester represented by formula (1); (b) a polyimide; (c) a photo radical initiator; (d) a radical polymerizable compound; and (e) a solvent for dissolving the photosensitive polyimide

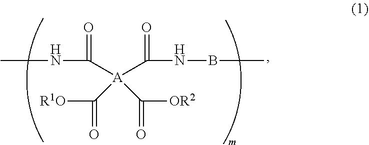

in which A, B, R¹, R², and m have the meaning as defined herein.

### BACKGROUND OF THE INVENTION

### Field of the Invention

The present invention relates to a photosensitive resin composition, and more particularly to a photosensitive resin composition having a low dissipation factor.

### Description of the Prior Art

In response to high-frequency wireless transmission and high-speed data communication, high-frequency chips and high-frequency substrates are the industrial focus of future development. High-frequency and high-speed transmission is required to ensure the integrity of the transmitted signal, so in the high-frequency (1 GHz or higher) region, a material with a low dissipation factor is required. In addition, with the development of technology and product requirements, the electronic design of printed circuit boards and semiconductors is required to have high-performance, compactness, and high-density wiring.

The photosensitive resin composition has been widely used as a cured film in various electronic components or devices, for it has excellent properties such as flexibility, good mechanical properties, and good electrical properties, and is preferred by related industries, such as semiconductor wafers (e.g. integrated circuit or IC) or printed circuit boards (PCB) industries. Among them, the photosensitive polyimide is most widely used, for example, the polyimide polymer containing methylacryloyl or acrylic groups. In response to the development of a photosensitive resin which is transmitted at a high frequency and high speed, a cured film from a photosensitive polyimide having a low dielectric loss tangent is expected to be developed.

### SUMMARY OF THE INVENTION

In view of the above, it is an object of the present invention to provide a cured film having a low dielectric constant and a low dielectric loss tangent.

To achieve the above objective, the present invention provides a resin composition, which comprises (a) a polyamide ester represented by formula (1); (b) a polyimide; (c) a photo radical initiator; (d) a radical polymerizable compound; and (e) a solvent for dissolving the polyimide;

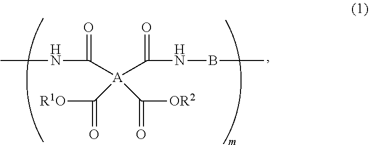

wherein A is derived from a tetracarboxylic dianhydride, B is derived from a diamine, m is a positive integer from 1 to 10,000, R¹ and R² are each independently a (meth)acryloxyalkyl group or an alkyl group, and the (meth)acryloxyalkyl group accounts for 50-100 mol % of the total of R¹ and R², provided that the tetracarboxylic dianhydride excludes pyromellitic dianhydride.

Preferably, the tetracarboxylic dianhydride is 1,4-bis(3,4-dicarboxyphenoxy)benzene dianhydride (HQDEA), 4,4′-bis(3,4-dicarboxyphenoxy)biphenyl dianhydride, 2,2-bis[4-(3,4-dicarboxyphenoxy)phenyl]propane dianhydride, 4,4′-(hexafluoroisopropylidene)diphthalic anhydride (BPADA), ethylene glycol bisanhydrotrimellitate (TMEG), propylene glycol bis(trimellitic anhydride) (TMPG), 1,2-propanediol bis(trimellitic anhydride), butanediol bis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(trimellitic anhydride) (TAHQ), hydroquinone bis(2-hydroxyethyl)ether bis(trimellitic anhydride), 2-phenyl-5-(2,4-xylyl)-1,4-hydroquinone bis(trimellitic anhydride), 2, 3-dicyanohydroquinone cyclobutane-1,2,3,4-tetracarboxylic dianhydride, 1,2,3,4-cyclopentanetetracarboxylic dianhydride (CPDA), 1,2,4,5-cyclohexane tetracarboxylic dianhydride (CHDA), bicyclo[2.2.1]heptane-2,3,5,6-tetracarboxylic dianhydride (BHDA), bicyclo[2.2.2]oct-7-ene-2,3,5,6-tetracarboxylic dianhydride (BOTDA), bicyclo[2.2.2]octane-2,3,5,6-tetracarboxylic dianhydride (BODA), 2,3,5-tricarboxy-cyclopentyl acetic dianhydride, bicyclo[2.2.1]heptane-2,3,5-tricarboxy-6-acetic dianhydride, decahydro-1,4,5,8-dimethanolnaphthalene-2,3,6,7-tetracarboxylic dianhydride, butane-1,2,3,4-tetracarboxylic dianhydride, 3,3′,4,4′-dicyclohexyltetracarboxylic dianhydride, or a combination of two or more thereof.

Preferably, the diamine is 2,2-bis-(3-aminophenyl)-1,1,1,3,3,3-hexafluoropropane (BAPP), 2,2-bis(4-aminophenyl)hexafluoropropane (APHF), 2,2′-bis(trifluoromethyl)benzidine (TFMB), 2,2′-dimethylbenzidine (m-tolidine), 1,3-bis(3-aminophenoxy)benzene (TPE-M), 1,3-bis(4-aminophenoxy)benzene (TPE-R), 1,4-bis(3-aminophenoxy)benzene, 1,4-bis(4-aminophenoxy)benzene (TPE-Q), 5-amino-2-(p-aminophenyl)benzoxazole (5-ABO), 6-amino-2-(p-aminophenyl)benzoxazole (6-ABO), or a combination of two or more thereof.

Preferably, the polyimide is represented by formula (2) below:

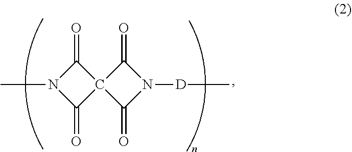

wherein C is derived from a tetracarboxylic dianhydride, D is derived from a diamine, and n is a positive integer from 1 to 5,000.

Preferably, at least one of C and D has a structure of at least one of the following divalent groups:

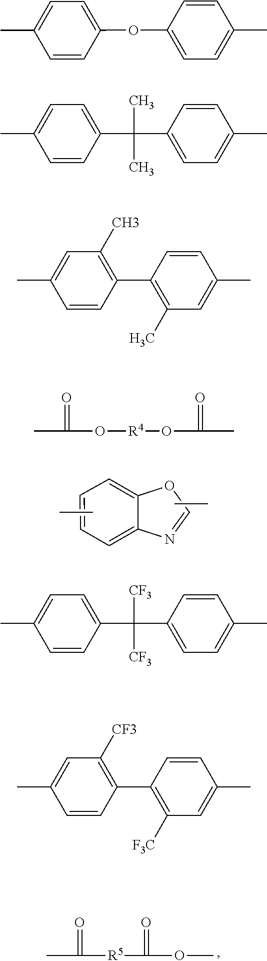

wherein R⁴ and R⁵ are each independently alkyl, alkenyl, alkynyl, aryl or heterocyclic.

Preferably, the radical polymerizable compound is a compound having at least two (meth)acrylate groups.

Preferably, a cured film formed from the resin composition has a glass transition temperature of 200 to 230° C.

Preferably, a cured film formed from the resin composition has a dissipation factor of less than 0.015.

The present invention also provides a cured film formed by curing the resin composition described above.

Preferably, the cured film has a glass transition temperature of 200 to 230° C.

Preferably, the cured film has a dissipation factor of less than 0.015.

The present invention further provides a method for producing a cured film, comprising the steps of: coating the resin composition described above on a substrate; and performing pre-baking, exposure, development, and post-baking on the composition in sequence.

The present invention further provides an interlayer insulating film and a circuit board protective film comprising the cured film described above.

The photosensitive resin composition of the present invention is composed of the above components (a) to (e), and a cured film having a low dissipation factor can be obtained by the composition.

### DETAILED DESCRIPTION OF THE EMBODIMENTS

The present invention provides a photosensitive resin composition, which comprises (a) a polyamide ester represented by formula (1); (b) a polyimide; (c) a photo radical initiator; (d) a radical polymerizable compound; and (e) a solvent for dissolving the polyimide;

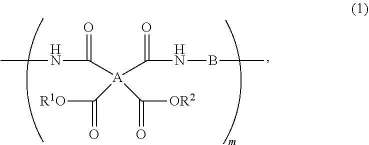

wherein A is derived from a tetracarboxylic dianhydride, B is derived from a diamine, m is a positive integer from 1 to 10,000, R¹ and R² are each independently a (meth)acryloxyalkyl group or an alkyl group, and the (meth)acryloxyalkyl group accounts for 50-100 mol % of the total of R¹ and R², provided that the tetracarboxylic dianhydride excludes pyromellitic dianhydride.

In the present invention, the dielectric constant and dielectric loss tangent can be reduced by increasing the crystallinity of the polyimide ester and decreasing the proportion of imide groups in the overall formulation. Based on that consideration, the structure of nonpolar groups (such as alkane, fluoroalkane), an ether, an ester, or an aromatic ring structure having a plane can be introduced into the structure of the polyimide ester by selecting a corresponding tetracarboxylic dianhydride from which A is derived and a corresponding diamine from which B is derived.

In the formula (1), m is a positive integer of 1-10000, such as: 1000, 2000, 3000, 4000, 5000, 6000, 7000, 8000, 9000. In some embodiments, m is between any two of the foregoing values. In the formula (1), R¹ and R² are each independently a (meth)acryloxyalkyl group or an alkyl group, and the (meth)acryloxyalkyl group accounts for 50 to 100 mol % of the total of R¹ and R², such as: 55-95 mol %, 60-90 mol %, or 65-85 mol %. In other words, the alkyl group accounts for 0-50 mol % of the total of R¹ and R², such as: 5-45 mol %, 10-40 mol %, or 15-35 mol %.

In a preferred embodiment, the polyamide ester represented by the formula (1) is obtained by reacting a tetracarboxylic dianhydride, an alcohol compound, and a diamine. Examples of the alcohol compound may be methanol, ethanol, n-propanol, isopropanol, n-butanol, 2-hydroxyethyl acrylate, 2-hydroxyethyl methacrylate, 2-hydroxypropyl acrylate, 2-hydroxypropyl methacrylate and the like. These alcohol compounds may be used singly or in combination of two or more (for example, two, three, or four) thereof.

In the present invention, the alkyl group means a linear or branched alkyl group, such as methyl, ethyl, n-propyl, isopropyl, n-butyl or isobutyl.

In formula (I), the tetracarboxylic dianhydride is preferably 1,4-bis(3,4-dicarboxyphenoxy)benzene dianhydride (HQDEA), 4,4′-bis(3,4-dicarboxyphenoxy)biphenyl dianhydride, 2,2-bis[4-(3,4-dicarboxyphenoxy)phenyl]propane dianhydride, 4,4′-(hexafluoroisopropylidene)diphthalic anhydride (BPADA), ethylene glycol bisanhydrotrimellitate (TMEG), propylene glycol bis(trimellitic anhydride) (TMPG), 1,2-propanediol bis(trimellitic anhydride), butanediol bis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(trimellitic anhydride) (TAHQ), hydroquinone bis(2-hydroxyethyl)ether bis(trimellitic anhydride), 2-phenyl-5-(2,4-xylyl)-1,4-hydroquinone bis(trimellitic anhydride), 2, 3-dicyanohydroquinone cyclobutane-1,2,3,4-tetracarboxylic dianhydride, 1,2,3,4-cyclopentanetetracarboxylic dianhydride (CPDA), 1,2,4,5-cyclohexane tetracarboxylic dianhydride (CHDA), bicyclo[2.2.1]heptane-2,3,5,6-tetracarboxylic dianhydride (BHDA), bicyclo[2.2.2]oct-7-ene-2,3,5,6-tetracarboxylic dianhydride (BOTDA), bicyclo[2.2.2]octane-2,3,5,6-tetracarboxylic dianhydride (BODA), 2,3,5-tricarboxy-cyclopentyl acetic dianhydride, bicyclo[2.2.1]heptane-2,3,5-tricarboxy-6-acetic dianhydride, decahydro-1,4,5,8-dimethanolnaphthalene-2,3,6,7-tetracarboxylic dianhydride, butane-1,2,3,4-tetracarboxylic dianhydride, 3,3′,4,4′-dicyclohexyltetracarboxylic dianhydride, or a combination of two or more (for example, two, three, four, or five) thereof.

In formula (I), the diamine is preferably 2,2-bis-(3-aminophenyl)-1,1,1,3,3,3-hexafluoropropane (BAPP), 2,2-bis(4-aminophenyl)hexafluoropropane (APHF), 2,2′-bis(trifluoromethyl)benzidine (TFMB), 2,2′-dimethylbenzidine (m-tolidine), 1,3-bis(3-aminophenoxy)benzene (TPE-M), 1,3-bis(4-aminophenoxy)benzene (TPE-R), 1,4-bis(3-aminophenoxy)benzene, 1,4-bis(4-aminophenoxy)benzene (TPE-Q), 5-amino-2-(p-aminophenyl)benzoxazole (5-ABO), 6-amino-2-(p-aminophenyl)benzoxazole (6-ABO), or a combination of two or more (for example, two, three, four, or five) thereof.

The polyimide of the present invention is a solvent-soluble polyimide, which is prepared by the chemical cyclodehydration or thermal cyclodehydration of a diamine and a tetracarboxylic dianhydride. The solvent may be ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate, methyl ethyl ketone, cyclohexanone, cyclopentanone, N-methylpyrrolidone, dimethylformamide, dimethyl sulfoxide, N,N-dimethylacetamide, or a combination of two or more thereof. The solid portion of the solvent-soluble polyimide is usually from 5% to 70% by weight of the solvent, more preferably from 10% to 50% by weight of the solvent. More specifically, the diamine and the tetracarboxylic dianhydride are usually dissolved in an organic solvent, and the resulting solution is stirred under controlled temperature conditions until the polymerization of tetracarboxylic dianhydride and diamine is completed, obtaining a polyimide precursor (i.e. polyamic acid). The concentration of the obtained polyamic acid solution is usually from 5% to 35% by weight, preferably from 10% to 30% by weight. When the concentration is within the range mentioned above, an appropriate molecular weight and solution viscosity can be obtained. In the present invention, the polymerization method is not particularly limited, and the order of addition, the combination of the monomers, and the adding amount thereof are not particularly limited. For example, the polyimide of the present invention can undergo random or sequential polymerization of block components by conventional polymerization methods.

The preparation method for the polyimide by cyclodehydration of the polyimide precursor (polyamic acid) is not particularly limited. More specifically, the chemically cyclodehydration method can be used, which adds pyridine, triethylamine, or N,N-diisopropylethylamine, etc. that are optionally acting as an alkaline reagent and acetic anhydride serving as a dehydration agent into the polyamic acid under nitrogen or oxygen atmosphere. After the reaction is completed, the resultant colloid is washed by water and filtered to obtain the polyimide powder. Alternatively, the thermal cyclodehydration method may be used, which adds an azeotropic reagent (such as toluene or xylene, but not limited thereto) into the polyamic acid, raises the temperature up to 180 degrees Celsius, and then removes the water produced from the cyclodehydration of the polyamic acid and the azeotropic reagent. After the reaction is completed, the solvent-soluble polyimide can be obtained. In the preparation of the solvent-soluble polyimide, other reagents which enhance the reaction efficiency may be added, such as, but not limited to, a catalyst, an inhibitor, an azeotropic agent, a leveling agent, or a combination of two or more (such as three or four) thereof.

In the present invention, the polyimide is preferably represented by formula (2) below:

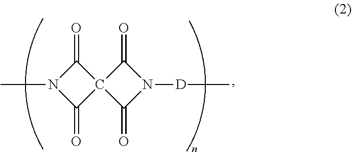

wherein C is derived from a tetracarboxylic dianhydride, D is derived from a diamine, and n is a positive integer from 1 to 5,000, such as 500, 1000, 1500, 2000, 2500, 3000, 3500, 4000, or 4500. In some embodiments, n is between any two of the foregoing values.

In the present invention, the polyimide represented by formula (2) is obtained by polymerizing a tetracarboxylic dianhydride with a diamine. That is, in formula (2), C is a tetravalent organic group derived from the tetracarboxylic dianhydride, and D is a divalent organic group derived from the diamine.

In formula (2), the tetracarboxylic dianhydride is not particularly limited, but based on the consideration of low dissipation factor, the tetracarboxylic dianhydride is preferably 3,3′,4,4′-biphenyltetracarboxylic dianhydride, 3,3′,4,4′-benzophenone tetracarboxylic dianhydride, 4,4′-oxydiphthalic anhydride, bis(3,4-dicarboxyphenyl)methane dianhydride, 2,2-bis(3,4-dicarboxyphenyl)propane dianhydride, 2,2-bis(3,4-dicarboxyphenyl)propane dianhydride, 1,3-bis(3,4-dicarboxyphenoxy)benzene dianhydride, 1,4-bis(3,4-dicarboxyphenoxy)benzene dianhydride, 4,4′-bis(3,4-dicarboxyphenoxy)biphenyl dianhydride, 2,2-bis[4-(3,4-dicarboxyphenoxy)phenyl]propane dianhydride, ethylene glycol bis(trimellitic anhydride) (TMEG), propylene glycol bis(trimellitic anhydride) (TMPG), 1,2-propanediol bis(trimellitic anhydride), butanediol bis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(2-hydroxyethyl)ether bis(trimellitic anhydride), 2-phenyl-5-(2,4-xylyl)-1,4-hydroquinone bis(trimellitic anhydride), 2, 3-dicyanohydroquinone cyclobutane-1,2,3,4-tetracarboxylic dianhydride, 1,2,3,4-cyclopentanetetracarboxylic dianhydride, 1,2,4,5-cyclohexane tetracarboxylic dianhydride, bicyclo[2.2.1]heptane-2,3,5,6-tetracarboxylic dianhydride, bicyclo[2.2.2]oct-7-ene-2,3,5,6-tetracarboxylic dianhydride, bicyclo[2.2.2]octane-2,3,5,6-tetracarboxylic dianhydride, 2,3,5-tricarboxy-cyclopentyl acetic dianhydride, bicyclo[2.2.1]heptane-2,3,5-tricarboxy-6-acetic dianhydride, decahydro-1,4,5,8-dimethanolnaphthalene-2,3,6,7-tetracarboxylic dianhydride, butane-1,2,3,4-tetracarboxylic dianhydride, 3,3′,4,4′-dicyclohexyltetracarboxylic dianhydride, or a combination of two or more (such as two, three, four, five) thereof.

In formula (2), the diamine may be an aromatic diamine or aliphatic diamine, but based on the consideration of low dissipation factor, the aromatic diamine is preferably 3,3′-diaminodiphenyl sulfone, 4,4′-diaminodiphenyl sulfone, 3,3′-methylenediphenylamine, 4,4′-methylenediphenylamine, 2,2-bis(4-aminophenyl)propane, 2,2-bis(4-aminophenyl)hexafluoropropane, 2,2′-bis(trifluoromethyl)benzidine, 2,2′-dimethylbenzidine, 3,3′-dihydroxybenzidine, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]-1,1,1,3,3,3-hexafluoropropane, 1,3-bis[4-(3-aminophenoxy)benzoyl]benzene, 4,4′-diaminobenzanilide, 2,2-bis(3-amino-4-hydroxyphenyl)hexafluoropropane, 5-amino-2-(p-aminophenyl)benzoxazole, 6-amino-2-(p-aminophenyl)benzoxazole, or a combination of two or more thereof. In addition, based on the consideration of low dissipation factor, the aliphatic diamine is preferably 1,4-diaminocyclohexane, 4,4′-diaminodicyclohexylmethane, or a combination thereof.

In formula (2), preferably, at least one of C and D has a structure of at least one of the following divalent groups:

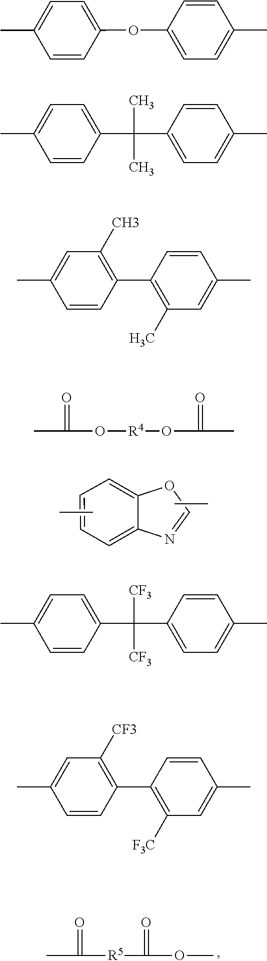

wherein R⁴ and R⁵ are each independently alkyl, alkenyl, alkynyl, aryl or heterocyclic group.

In the present invention, a commercially available product can be used as the soluble polyimide, for example, those sold under the trade name “PIAD100H”, “PIAD100L”, or “PIAD200” (manufactured by Arakawa Chemical Co., Ltd.) can be used.

In the present invention, the polyimide is preferably added in an amount of 10 wt % to 100 wt %, more preferably 20 wt % to 80 wt %, particularly preferably 30 wt % to 70 wt % of the main resin (i.e., the polyamide ester).

In the present invention, the photo radical initiator may be an initiator commonly used in conventional photosensitive resin composition. Examples of the photo radical initiator includes, but are not limited to, an oxime compound such as oxime derivatives, a ketone compound (including acetophenones, benzophenones, and thioxanthone compounds), a triazine compound, a benzoin compound, a metallocene compound, a triazine compound, an acylphosphine compound, and a combination of two or more (such as three, four, or five) thereof. From the viewpoint of exposure sensitivity, the photo radical initiator is preferably an acylphosphine compound or an oxime compound.

Examples of the oxime compound such as oxime derivatives may include, but are not limited to, O-acyloxime-based compounds, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl] ethyl ketone, O-ethoxycarbonyl-α-oxyamino-1-phenylpropan-1-one, and a combination of two or more (such as three, four, five) thereof. Examples of the O-acyloxime-based compound may include, but are not limited to, 1,2-octanedione, 2-dimethylamino-2-(4-methylbenzyl)-1-(4-morpholine-4-yl-phenyl)-butan-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octan-1-oxime-O-acetate, 1-(4-phenylsulfanylphenyl)-butan-1-oxime-O-acetate, and a combination of two or more thereof. Examples of the acylphosphine compound include, but are not limited to, bis(2,4,6-trimethylbenzoyl)phenylphosphine oxide, 2,4,6-trimethylbenzoyl-diphenyloxophosphine, and a combination thereof.

The content of the photo radical initiator is preferably 0.1 wt % to 30 wt %, more preferably 1 wt % to 20 wt % of the main resin (i.e., the polyamide ester). When the content of the photo radical initiator is within the range mentioned above, excellent reliability, better resolution of the pattern, and heat resistance, light resistance and chemical resistance resulted from compact contact can be ensured because sufficient curing is achieved while exposure to light during pattern formation.

The photo radical initiator can be used with a photosensitizer that is able to cause a chemical reaction by absorbing light and being excited, and then transfer its energy. Examples of the photosensitizer may include, but are not limited to, tetraethylene glycol bis-3-mercaptopropionate, pentaerythritol tetrakis-3-mercaptopropionate, dipentaerythritol tetraalkyl-3-mercaptopropionate, and the like. These photosensitizers may be used singly or in combination of two or more (such as three) thereof.

The radical polymerizable compound is a photo radical crosslinking agent, and does not have particularly limited types. Preferably, the type of the photocrosslinking agent depends on the type of the polyamide ester, the soluble polyimide, and/or the photo radical initiator. In a preferred embodiment of the present invention, the radical polymerizable compound is a compound having at least two (meth)acrylate groups, such as the compound having two (meth)acrylate groups, the compound having three (meth)acrylate groups, the compound having four (meth)acrylate groups, the compound having five (meth)acrylate groups, or the compound having six (meth)acrylate groups. Examples of the compound having at least two (meth)acrylate groups include, but are not limited to, ethylene glycol dimethacrylate; EO modified diacrylate of bisphenol A (n=2 to 50) (EO being Ethylene oxide, and n being the molar number of ethylene oxide added); EO modified diacrylate of bisphenol F; Aronix M-210®, M-240®, and/or M-6200® (manufactured by Toagosei Synthetic Chemical Co., Ltd.); KAYARAD HDDA®, HX-220®, R-604® and/or R-684® (Nippon Kayaku Co., Ltd.); V-260®, V-312®, and/or V-335HP® (Osaka Organic Chemical Ind., Ltd.); BLEMMER PDE-100®, PDE-200®, PDE-400®, PDE-600®, PDP-400®, PDBE-200A®, PDBE-450A®, ADE-200®, ADE-300®, ADE-400A®, ADP-400® (NOF Co., Ltd.); Trimethylolpropane triacrylate (TMPTA); methylolpropane tetraacrylate; Glycerine propoxylate triacrylate; triethoxytrimethylolpropane triacrylate; trimethylolpropane trimethacrylate; tris(2-hydroxyethyl)isocyanate triacrylate (THEICTA); pentaerythritol triacrylate; pentaerythritol hexaacrylate; Aronix M-309®, M-400®, M-405®, M-450®, M-710®, M-8030®, and/or M-8060® (Toagosei Synthetic Chemical Co., Ltd.); KAYARAD DPHA®, TMPTA®, DPCA-20®, DPCA-30®, DPCA-60®, and/or DPCA-120® (Nippon Chemical Co., Ltd.); V-295®, V-300®, V-360®, V-GPT®, V-3PA®, and/or V-400® (Osaka Yuki Kayaku Kogyo Co., Ltd), etc.

In the photosensitive resin composition, the content of the radical polymerizable compound is preferably 1% to 50% by mass, based on the total solid content of the photosensitive resin composition, from the viewpoint of good radical polymerizability and heat resistance. The lower limit is more preferably 5% by mass or more. The upper limit is more preferably 30% by mass or less. The radical polymerizable compound may be used singly or in combination of two or more (for example, three, four, five) thereof. Further, the mass ratio of the polyamide ester to the radical polymerizable compound is preferably from 98/2 to 10/90, more preferably from 95/5 to 30/70, particularly preferably from 90/10 to 50/50. When the mass ratio of the polyamide ester to the radical polymerizable compound is in the above range, a cured film having more excellent curability and heat resistance can be formed. In the present invention, the radical polymerizable compound may be used singly or in combination of two or more (for example, three, four, or five) thereof. When two or more kinds of the radical polymerizable compound are used, it is preferable that the total amount of the radical polymerizable compound is within the above range.

When the content of the radical polymerizable compound is within the above range, the cross-linking bond produced by the radical reaction initiated by the photo radical initiator and the UV radiation can improve the pattern forming ability. In addition, curing by exposure can be sufficiently achieved during pattern formation, and the contrast of the alkaline developer can be improved.

The solvent used in the present invention is not particularly limited as long as it can dissolve the polyimide. Examples of the solvent include, but are not limited to, ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate, methyl ethyl ketone, cyclohexanone, cyclopentanone, N-methylpyrrolidone, dimethylformamide, dimethyl sulfoxide or N,N-dimethylacetamide (DMAc). These solvents may be used singly or in combination of two or more (such as two, three or four) thereof. From the viewpoint of improving the state of the coated surface, it is preferred to mix two or more kinds of solvents. From the viewpoint of coatability, when the photosensitive resin composition contains the solvent, the content of the solvent is preferably 5% to 80% by mass, more preferably 5% to 70% by mass, and particularly preferably 10% to 60% by mass, based on the total solid amount of the photosensitive resin composition. One or two or more kinds of solvent could be used. When two or more kinds of solvent are used, it is preferable that the total amount of the solvents is within the above range.

The photosensitive resin composition of the present invention may be added or may not be added with an additive, depending on the application requirements of the user, provided that the effects of the present invention are not affected. Examples of the additive include, but are not limited to, higher fatty acid derivatives, surfactants, inorganic particles, curing agent, curing catalysts, fillers, antioxidants, ultraviolet absorbers, anticoagulants, leveling agents or a combination of two or more thereof. When the additives are formulated, the total amount of the additives is preferably 10% by mass or less, based on the solid amount of the photosensitive resin composition.

The interlayer insulating film and the protective film of the present invention can be prepared by spin coating or cast coating, which coats a substrate with the photosensitive polyimide resin composition, followed by prebaking to remove the solvent and then form a pre-baked film. The prebaking conditions vary depending on the kind and formulation ratio of the individual components, and are usually at a temperature of 80 to 120° C. for 5 to 15 minutes. After prebaking, the coating film is exposed through a mask, and the light used for exposure is preferably ultraviolet of g-line, h-line, i-line, etc., and the ultraviolet irradiation device may be (ultra) high-pressure mercury lamp and metal halogen lamp. Then, the exposed film is immersed in a developing solution at a temperature of 20 to 40° C. for 1 to 2 minutes to remove the unnecessary portions and form a specific pattern. Examples of the developer include, but are not limited to, methanol, ethanol, propanol, isopropanol, butanol, ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, methyl ethyl ketone, cyclohexanone, cyclopentanone, N-methyl pyrrolidone, dimethylformamide, dimethyl sulfoxide, N,N-dimethylacetamide, and a combination of two or more thereof.

When a developer composed of the above organic solvents is used, an organic solvent is usually used for washing after development, followed by air-drying with compressed air or compressed nitrogen. Next, post-baking treatment is performed using a heating device such as a hot plate or an oven, and the temperature of the post-baking treatment is usually between 180 to 250° C. After the above processing steps, a protective film can be formed.

The substrate is not particularly limited in the present invention and may be selected according to subsequent needs. The substrate may be copper, graphite, aluminum, iron, copper alloy, aluminum alloy, iron alloy, a silicon wafer, a plastic material, or the like.

The substrate may also be an alkali-free glass applied to a liquid crystal display, a soda-lime glass, a tempered glass (Pyrex glass), a quartz glass, a glass having a transparent conductive film adhered thereon, or a photoelectric conversion device substrate (for example, a silicon substrate) used in a solid-state imaging device, or the like.

The element having the interlayer insulating film or the protective film includes the interlayer insulating film or the protective film as described above, and the above-mentioned substrate.

The element having the interlayer insulating film or the protective film includes, but is not limited to, a substrate-like printed circuit board, a display device, a semiconductor device, a printed circuit board, an optical waveguide, or the like.

Accordingly, the present invention also provides a cured film obtained by curing the resin composition as described above. In a preferred embodiment, the cured film preferably has a glass transition temperature of 200 to 230° C. The cured film of the present invention preferably has a dissipation factor of less than 0.015; more preferably has a dissipation factor of 0.01; and particularly preferably has a dissipation factor of 0.002 to 0.009.

The present invention further provides an interlayer insulating film and a circuit board protective film comprising the cured film described above. Examples of the interlayer insulating film include, but are not limited to, an interlayer insulating film for a rewiring layer or an interlayer insulating film for a substrate-like printed circuit board.

The invention further provides a method for producing a cured film, comprising the steps of: coating the resin composition described above on a substrate; and performing pre-baking, exposure, development, and post-baking on the resin composition in sequence.

To highlight the efficacy of the present invention, the inventors have completed the examples and comparative examples in the manners set forth below. The following examples and comparative examples are experimental data of the inventors and do not fall in the scope of the prior art. The following examples and comparative examples are intended to further illustrate the present invention, but not intended to limit the scope of the invention. Any changes and modifications made by those skilled in the art without departing from the spirit of the invention are within the scope of the invention.

### Synthesis Example 1: Synthesis of Polyamide Ester (A1) by Propylene Glycol bis(trimellitic anhydride) (TMPG), 2,2′-bis(trifluoromethyl)benzidine (TFMB), and 2-hydroxyethyl Methacrylate (HEMA)

In a four-necked flask, 16.97 g (40.0 mmol) of propylene glycol bis(trimellitic anhydride) (TMPG), 10.94 g (84.0 mmol) of 2-hydroxyethyl methacrylate (HEMA), 0.04 g (0.4 mmol) of hydroquinone, 3.16 g (84.0 mmol) of pyridine, and 80 mL of tetrahydrofuran were added sequentially and then stirred at 50° C. for 3 hours, and a clear solution was obtained after a few minutes from the start of heating. The reaction mixture was cooled to room temperature, and then cooled to −10° C. While maintaining the temperature at −10° C.±4° C., 11.9 g (100.0 mmol) of thionyl chloride was added over 10 minutes. The viscosity increases during the addition of thionyl chloride. After dilution with 50 mL of dimethylacetamide, the reaction mixture was stirred at room temperature for 2 hours. Then the temperature was kept at −10° C.±4° C., and 11.62 g (200.0 mmol) of propylene oxide as a neutralizing agent was used to neutralize excess hydrochloric acid. Afterwards, a solution of 12.75 g (39.8 mmol) of 2,2′-bis(trifluoromethyl)benzidine (TFMB) dissolved in 100 mL of dimethylacetamide was added dropwise to the reaction mixture over 20 minutes, and then the reaction mixture was stirred at room temperature for 15 hours. After the reaction is completed, the polyimide precursor was precipitated by 5 liters of water, and the water-polyimide precursor mixture was stirred at 5000 rpm for 15 minutes. The polyimide precursor was obtained after filtration, and then poured again into 4 liters of water, stirred for 30 minutes, and subjected to filtration again. Thereafter, the obtained polyimide precursor was dried at 45° C. for 3 days under reduced pressure to obtain powder of polyamide ester (HEMA-TMPG-TFMB PAE (A1)). The test results of the resulted A1 by ¹H-NMR are shown below (the ratio of hydrogen number is defined by the non-repeating structure unit). ¹H-NMR (500 MHz, DMSO-d₆, δ ppm): 11.10-11.07 (2H, m, NH), 8.46-8.43 (2H, m), 8.39-8.32 (2H, m), 8.12-8.01 (2H, m), 7.60-7.38 (4H, m), 7.30-7.23 (2H, m), 4.49-4.30 (12H, m), 2.49-2.40 (2H, m), 1.84-1.80 (6H, m); FT-IR (cm⁻¹): 2923, 2821 (C—H), 1780 (C═O), 1725 (C═O), 1648 (CH2=CH), 1615, 1485, 1425, 1366, 1273, 1241, 1198, 1134, 1078, 842, 742.

### Synthesis Example 2: Synthesis of Polyamide Ester (A2) by 2,2-bis[4-(3,4-dicarboxyphenoxy)phenyl]propane Dianhydride (BPADA), 1,4-bis(4-aminophenoxy)benzene (TPE-Q), and 2-hydroxyethyl Methacrylate (HEMA)

In a four-necked flask, 20.82 g (40.0 mmol) of BPADA, 10.94 g (84.0 mmol) of HEMA, 0.04 g (0.4 mmol) of hydroquinone, 3.16 g (84.0 mmol) of pyridine, and 80 mL of tetrahydrofuran were added sequentially and then stirred at 50° C. for 3 hours to obtain a diester of propylene glycol bis(trimellitic anhydride) and 2-hydroxyethyl methacrylate. The obtained diester was acyl-chlorinated by thionyl chloride, and then converted into a polyimide precursor by 1,4-bis(4-aminophenoxy)benzene (TPE-Q) using the same method as in Synthesis Example 1. Then, powder of polyamide ester (HEMA-BPADA-TPE-Q PAE (A2)) was obtained from the polyimide precursor in the same manner as in Synthesis Example 1. The test results of the resulted A2 by ¹H-NMR are shown below (the ratio of hydrogen number is defined by the non-repeating structure unit). ¹H-NMR (500 MHz, DMSO-d₆, δ ppm): 10.41-10.40 (2H, m, NH), 8.30-8.24 (2H, m), 7.98-7.85 (2H, m), 7.78-7.61 (6H, m), 7.39-7.20 (8H, m), 7.13-6.95 (12H, m), 6.00-5.93 (2H, m), 5.61-5.55 (2H, m), 4.44-4.41 (4H, m), 4.27-4.17 (4H, m), 1.81-1.68 (12H, m); FT-IR (cm⁻¹): 2927 (C—H), 2824, 1726 (C═O), 1651 (CH2=CH), 1615, 1483, 1435, 1370, 1132, 1078, 842, 743.

### Synthesis Example 3: Synthesis of Polyamide Ester (A3) by 2,2-bis[4-(3,4-dicarboxyphenoxy)phenyl]propane Dianhydride (BPADA), 2,2′-bis(trifluoromethyl)benzidine (TFMB), 2-hydroxyethyl Methacrylate (HEMA), and Ethanol (EtOH)

In a four-necked flask, 20.82 g (40.0 mmol) of BPADA, 5.47 g (42.0 mmol) of HEMA, 1.93 g (42.0 mmol) of ethanol, 0.04 g (0.4 mmol) of hydroquinone, 3.16 g (84.0 mmol) of pyridine, and 80 mL of tetrahydrofuran were added sequentially and then stirred at 50° C. for 3 hours to obtain a diester of propylene glycol bis(trimellitic anhydride), 2-hydroxyethyl methacrylate and ethanol. The obtained diester was acyl-chlorinated by thionyl chloride, and then converted into a polyimide precursor by 2,2′-bis(trifluoromethyl)benzidine (TFMB) using the same method as in Synthesis Example 1. Then, powder of polyamide ester (1:1 HEMA-EtOH-BPADA-TFMB PAE (A3)) was obtained from the polyimide precursor in the same manner as in Synthesis Example 1. The test results of the obtained A3 by ¹H-NMR are shown below (the ratio of hydrogen number is defined by the non-repeating structure unit). ¹H-NMR (500 MHz, DMSO-d₆, δ ppm): 10.84-10.82 (2H, m, NH), 8.28-8.26 (2H, m), 7.98-7.85 (2H, m), 7.77-7.68 (2H, m), 7.40-7.26 (8H, m), 7.24-7.03 (6H, m), 6.00-5.93 (1H, m), 5.61-5.55 (1H, m), 4.46-4.41 (2H, m), 4.27-4.18 (4H, m), 1.81-1.76 (9H, m), 1.12-1.08 (3H, m); FT-IR (cm⁻¹): 2927 (C—H), 1780, 1726 (C═O), 1650 (CH2=CH), 1615, 1484, 1434, 1370, 1132, 1078, 742.

### Synthesis Example 4: Synthesis of Polyimide (B1: Solvent-Soluble Polyimide) by Propylene Glycol Bis(Trimellitic Anhydride) (TMPG) and 2,2′-Bis(Trifluoromethyl)Benzidine (TFMB)

62.12 g (0.194 mmol) of TFMB and 500 g of DMAc were placed in a three-necked flask. After stirring at 30° C. till complete dissolution, 84.86 g (0.200 mmol) of TMPG was added, followed by continuous stirring and reaction at 25° C. for 24 hours to obtain a polyamic acid solution. Then, 23.00 g (0.290 mmol) of pyridine and 59.4 g (0.582 mmol) of acetic anhydride were further added, followed by continuous stirring and reaction at 25° C. for 24 hours. After the reaction is completed, polyimide was precipitated by 5 liters of water, and the water-polyimide mixture was stirred at 5000 rpm for 15 minutes. The polyimide was obtained after filtration, and then poured again into 4 liters of water, stirred for 30 minutes, and subjected to filtration again. Thereafter, the obtained polyimide was dried at 45° C. for 3 days under reduced pressure to obtain powder of dried polyimide (TMPG-TFMB PI (B1)). The test results of the resulted B1 by ¹H-NMR are shown below (the ratio of hydrogen number is defined by the non-repeating structure unit). ¹H-NMR (500 MHz, DMSO-d₆, δ ppm): 8.47-8.20 (4H, m), 8.15-7.70 (6H, m), 7.47-7.41 (2H, m), 4.45-4.38 (4H, m), 2.48-2.39 (2H, m); FT-IR (cm⁻¹): 3066, 2971, 1785, 1722, 1605, 1490, 1431, 1315, 1278, 1145, 840, 722.

### Synthesis Example 5: Synthesis of Polyimide (B2: Soluble Polyimide) by 2,2-bis[4-(3,4-dicarboxyphenoxy)phenyl]propane Dianhydride (BPADA), 2,2′-bis(trifluoromethyl)benzidine (TFMB), and 2,2-bis[4-(4-aminophenoxy)phenyl]propane (BAPP)

15.53 g (0.0485 mmol) of TFMB, 19.91 g (0.0485 mmol) of BAPP, and 234 g of DMAc were placed in a three-necked flask. After stirring at 30° C. till complete dissolution, 52.04 g (0.100 mmol) of BPADA was added, followed by continuous stirring and reaction at 25° C. for 24 hours to obtain a polyamic acid solution. Then, 11.50 g (0.146 mmol) of pyridine and 29.7 g (0.291 mmol) of acetic anhydride were further added, followed by continuous stirring and reaction at 25° C. for 24 hours. After the reaction was completed, polyimide was precipitated by 5 liters of water, and the water-polyimide mixture was stirred at 5000 rpm for 15 minutes. The polyimide was obtained after filtration, and then poured again into 4 liters of water, stirred for 30 minutes, and subjected to filtration again. Thereafter, the obtained polyimide was dried at 45° C. for 3 days under reduced pressure to obtain powder of dried polyimide (BPADA-TFMB-BAPP PI (B2)). The test results of the resulted B2 by ¹H-NMR are shown below (the ratio of hydrogen number is defined by the non-repeating structure unit). ¹H-NMR (500 MHz, DMSO-d₆, δ ppm): 8.02-7.95 (8H, m), 7.83-7.81 (2H, m), 7.66-7.61 (2H, m), 7.47-7.24 (22H, m), 7.18-6.81 (16H, m), 1.70-1.64 (18H, m); FT-IR (cm⁻¹): 3066, 2971, 1778, 1726, 1601, 1486, 1426, 1310, 1273, 1138, 1078, 840, 722.

### Comparative Synthesis Example 1: Synthesis of Polyamide Ester (A4) by Pyromellitic Dianhydride (PMDA), 2,2′-bis(trdfluoromethyl)benzidine (TFMB), and 2-hydroxyethyl methacrylate (HEMA)

In a four-necked flask, 8.72 g (40.0 mmol) of PMDA, 10.94 g (84.0 mmol) of HEMA, 0.04 g (0.4 mmol) of hydroquinone, 3.16 g (84.0 mmol) of pyridine, and 80 mL of tetrahydrofuran were added sequentially and then stirred at 50° C. for 3 hours to obtain a diester of pyromellitic dianhydride and 2-hydroxyethyl methacrylate. The obtained diester was acyl-chlorinated by thionyl chloride, and then converted into a polyimide precursor by 2,2′-bis(trifluoromethyl)benzidine (TFMB) using the same method as in Synthesis Example 1. Then, polyamide ester (HEMA-PMDA-TFMB PAE (A4)) was obtained from the polyimide precursor in the same manner as in Synthesis Example 1. The test results of the resulted A4 by ¹H-NMR are shown below (the ratio of hydrogen number is defined by the non-repeating structure unit). ¹H-NMR (500 MHz, DMSO-d₆, δ ppm): 11.10-11.02 (2H, m, NH), 8.38-8.12 (4H, m), 7.94 (2H, s), 7.38 (2H, s), 6.01-6.00 (2H, m), 5.62-5.55 (2H, m), 4.52-4.56 (4H, m), 4.36-4.35 (4H, m), 1.84-1.80 (6H, m); FT-IR (cm⁻¹): 2975 (CH), 1730, 1628 (CH2=C), 1605, 1548, 1499, 1446, 1306, 1262, 1113, 896, 845, 745.

### Examples 1-5 and Comparative Examples 1-3: Preparation of Photosensitive Resin Compositions

The components used in the photosensitive polyimide resin composition are as follows. The components listed below were mixed with a solvent in a weight ratio as shown in Table 1 to prepare a DMAc solution having a solid content of 30%, which is a coating solution of a photosensitive resin composition.

Component A1: HEMA-TMPG-TFMB PAE

Component A2: HEMA-BPADA-TPE-Q PAE

Component A3: 1:1 HEMA-EtOH BPADA-TFMB PAE

Component A4: HEMA PMDA-TFMB PAE (Comparative Synthesis Example)

Component B1: TMPG-TFMB PI

Component B2: BPADA-TFMB-BAPP PI

Component C: Irgacure OXE01 (BASF)

Component D1: THEICTA (Aldrich)

Component D2: TMPTA (Aldrich)

Component D3: PDBE-450A (NOF)

Evaluation Results

[Pattern Formability]

The photosensitive resin composition was coated on a copper foil substrate, and then dried at 90° C. for 5 minutes to obtain a surface-dried film of 15 μm. After exposure through a photomask, the exposed layer of the photosensitive resin composition was developed for 60 seconds by using cyclopentanone. Whether the line width has good edge sharpness or not was evaluated by the following criteria. The smaller the line width of the photosensitive resin composition layer, the larger the difference between solubility of the light-irradiated portion and the non-light-irradiated portion with respect to the developer, resulting in preferable outcome. Further, the smaller the change in the line width with respect to the change in the exposure energy, the wider the exposure tolerance, which is a preferable result.

After observing the formed adhesive pattern by an optical microscope, the case where a thin line pattern having a line width/pitch width of 15 μm/15 μm or less was set to A, and the case where a thin line pattern having a line width/pitch width of more than 15 μm/15 μm and not more than 30 μm/30 μm was set to B to evaluate the pattern formability. The evaluation results are shown in Table 1.

The photosensitive resin composition was coated, exposed, developed, and then cured at 250° C. to form a film. Dielectric constant, dissipation factor, linear thermal expansion coefficient, and glass transition temperature listed in Table 1 was obtained by measuring the film using the following methodologies.

[Dielectric Constant (Dk)]

The measurement was carried out by a measuring instrument (Manufacturer: Agilent; model: HP4291) using the standard method of IPC-TM-650-2.5.5.9 under the condition of 10 GHz.

[Dissipation Factor (Df)]

The measurement was carried out by a measuring instrument (Manufacturer: Agilent; model: HP4291) using the standard method of IPC-TM-650-2.5.5.9 under the condition of 10 GHz.

[Coefficient of Thermal Expansion (CTE)]

By means of thermomechanical analysis, the average value in the range of 50° C. to 200° C. was calculated as the coefficient of thermal expansion from the extension of the test piece with a film thickness of 20 μm at a load of 3 g and a temperature increase rate of 10° C./min. The material with low coefficient of thermal expansion can avoid excessive deformation during the heating and baking process for manufacturing the circuit board, so that the production line can maintain a high yield.

[Glass Transition Temperature (Tg)]

The differential scanning calorimeter device (DSC-6220) manufactured by SII Nano Technology is used. The film of the photosensitive resin composition was subjected to the thermal experience under the following conditions under a nitrogen atmosphere. The conditions of the thermal experience were a first temperature rise (temperature rising rate: 10° C./min), followed by cooling (cooling rate: 30° C./min), followed by a second temperature rise (temperature rising rate: 10° C./min). The glass transition temperature of the present invention is read and determined by a value observed during the first or the second temperature rise.

TABLE 1

| | | | | | | | | Comparative | | |
|---|---|---|---|---|---|---|---|---|---|---|
| | | | Example | | | | | Example | | |
| | | | 1 | 2 | 3 | 4 | 5 | 1 | 2 | 3 |
| Formulation | polyamide | A1 | 40 | 40 | | | | | | |
| | ester | A2 | | | 40 | 40 | | | | |
| | | A3 | | | | | 40 | | | |
| | | A4 | | | | | | 40 | 40 | 80 |
| | soluble | B1 | 40 | | 40 | | 40 | 40 | | |
| | polyimide | B2 | | 40 | | 40 | | | 40 | |
| | photo | C | 4 | 4 | 4 | 4 | 4 | 4 | 4 | 4 |
| | radical | | | | | | | | | |
| | initiator | | | | | | | | | |
| | crosslinking | D1 | 16 | 16 | | | 16 | 16 | | |
| | agent | D2 | | | 16 | | | | 16 | |
| | | D3 | | | | 16 | | | | 16 |

| Exposure dose (mJ/cm²) | | 200 | 200 | 400 | 400 | 200 | 400 | 400 | 400 |
|---|---|---|---|---|---|---|---|---|---|
| Evaluation | Pattern | A | A | B | A | A | A | B | A |
| results | Formability | | | | | | | | |
| | Glass | 220 | 224 | 202 | 227 | 210 | 260 | 235 | 240 |
| | transition | | | | | | | | |
| | temp.(° C.) | | | | | | | | |
| | CTE | 66 | 68 | 63 | 57 | 67 | 41 | 55 | 60 |
| | (ppm/° C.) | | | | | | | | |
| | Dielectric | 2.82 | 2.59 | 2.89 | 2.92 | 2.70 | 3.14 | 2.75 | 2.69 |
| | constant (Dk) | | | | | | | | |
| | Dissipation | 0.0081 | 0.0079 | 0.0082 | 0.0085 | 0.0084 | 0.018 | 0.017 | 0.017 |
| | factor (Df) | | | | | | | | |

Note:
The unit of the components in Table 1 is part by weight.

As shown in Table 1, the cured films formed by the resin compositions of Examples 1 to 5 have a glass transition temperature of 200 to 230° C. and a coefficient of thermal expansion of about 55 to 70, and the dissipation factor is obviously lower than 0.01.

In summary, the cured film formed by the resin composition of the present invention has a low dielectric constant and a low dielectric loss tangent, and is suitable for use with the substrate in a substrate-like printed circuit board, a liquid crystal display, an organic electroluminescence display, a semiconductor device, or a printed circuit board.

Those described above are only the preferred embodiments of the present invention, and are not intended to limit the scope of the present invention. All the simple and equivalent variations and modifications made according to the claims and the description of the present invention are still within the scope of the present invention.

1. A photosensitive resin composition comprising (a) a polyamide ester represented by formula (1) below; (b) a polyimide; (c) a photo radical initiator; (d) a radical polymerizable compound; and (e) a solvent for dissolving the polyimide; 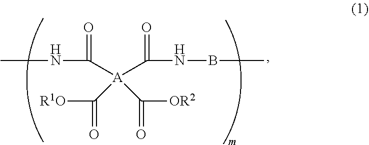
wherein A is derived from a tetracarboxylic dianhydride, Y is derived from a diamine, and m is a positive integer from 1 to 10,000, R¹ and R² are each independently a (meth)acryloxyalkyl group or an alkyl group, and the (meth)acryloxyalkyl group accounts for 50-100 mol % of the total of R¹ and R², provided that the tetracarboxylic dianhydride excludes pyromellitic dianhydride.

2. The resin composition according to claim 1, wherein the tetracarboxylic dianhydride is selected from the group consisting of 1,4-bis(3,4-dicarboxyphenoxy)benzene dianhydride (HQDEA), 4,4′-bis(3,4-dicarboxyphenoxy)biphenyl dianhydride, 2,2-bis[4-(3,4-dicarboxyphenoxy)phenyl]propane dianhydride, 4,4′-(hexafluoroisopropylidene)diphthalic anhydride (BPADA), ethylene glycol bisanhydrotrimellitate (TMEG), propylene glycol bis(trimellitic anhydride) (TMPG), 1,2-propanediol bis(trimellitic anhydride), butanediol bis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(trimellitic anhydride) (TAHQ), hydroquinone bis(2-hydroxyethyl)ether bis(trimellitic anhydride), 2-phenyl-5-(2,4-xylyl)-1,4-hydroquinone bis(trimellitic anhydride), 2,3-dicyanohydroquinone cyclobutane-1,2,3,4-tetracarboxylic dianhydride, 1,2,3,4-cyclopentanetetracarboxylic dianhydride (CPDA), 1,2,4,5-cyclohexane tetracarboxylic dianhydride (CHDA), bicyclo[2.2.1]heptane-2,3,5,6-tetracarboxylic dianhydride (BHDA), bicyclo[2.2.2]oct-7-ene-2,3,5,6-tetracarboxylic dianhydride (BOTDA), bicyclo[2.2.2]octane-2,3,5,6-tetracarboxylic dianhydride (BODA), 2,3,5-tricarboxy-cyclopentyl acetic dianhydride, bicyclo[2.2.1]heptane-2,3,5-tricarboxy-6-acetic dianhydride, decahydro-1,4,5,8-dimethanonaphthalene-2,3,6,7-tetracarboxylic dianhydride, butane-1,2,3,4-tetracarboxylic dianhydride, 3,3′,4,4′-dicyclohexyltetracarboxylic dianhydride, and combinations thereof.

3. The resin composition according to claim 1, wherein the diamine is selected from the group consisting of 2,2-bis-(3-aminophenyl)-1,1,1,3,3,3-hexafluoropropane (BAPP), 2,2-bis(4-aminophenyl)hexafluoropropane (APHF), 2,2′-bis(trifluoromethyl)benzidine (TFMB), 2,2′-dimethylbenzidine (m-tolidine), 1,3-bis(3-aminophenoxy)benzene (TPE-M), 1,3-bis(4-aminophenoxy)benzene (TPE-R), 1,4-bis(3-aminophenoxy)benzene, 1,4-bis(4-aminophenoxy)benzene (TPE-Q), 5-amino-2-(p-aminophenyl)benzoxazole (5-ABO), 6-amino-2-(p-aminophenyl)benzoxazole (6-ABO), and combinations thereof.

4. The resin composition according to claim 1, wherein the polyimide is represented by formula (2) below: 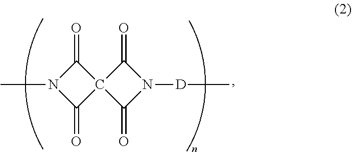
wherein C is derived from a tetracarboxylic dianhydride, D is derived from a diamine, and n is a positive integer from 1 to 5,000.

5. The resin composition according to claim 4, wherein at least one of C and D has a structure of at least one of the following divalent groups: 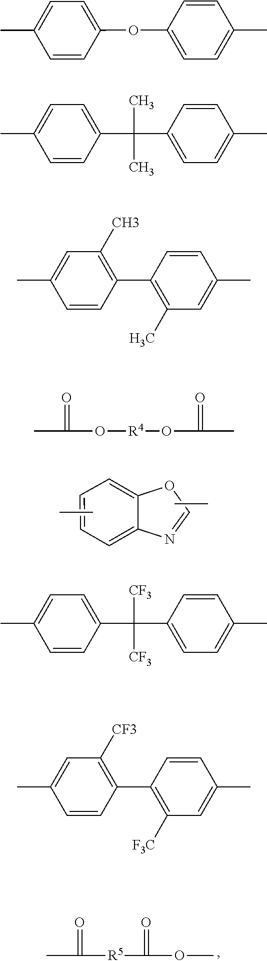
wherein R⁴ and R⁵ are each independently alkyl, alkenyl, alkynyl, aryl or heterocyclic.

6. The resin composition according to claim 1, wherein the radical polymerizable compound is a compound having at least two (meth)acrylate groups.

7. The resin composition according to claim 1, wherein a cured film formed therefrom has a glass transition temperature of 200 to 230° C.

8. The resin composition according to claim 1, wherein a cured film formed therefrom has a dissipation factor of less than 0.015.

9. A cured film formed by curing the resin composition according to claim 1.

10. The cured film according to claim 9, having a glass transition temperature of 200 to 230° C.

11. The cured film according to claim 9, having a dissipation factor of less than 0.015.

12. An interlayer insulating film, comprising the cured film according to claim 9.

13. A circuit board protective film, comprising the cured film according to claim 9.

14. A method for producing a cured film, comprising the steps of:
coating the resin composition according to claim 1 on a substrate; and
performing pre-baking, exposure, development, and post-baking on the resin composition in sequence.
